(19) United States
(12) Patent Application Publication
(10) Pub. No.: US 2018/0053478 A1
(43) Pub. Date: Feb. 22, 2018

(54) LIQUID CRYSTAL DISPLAY PANEL AND DRIVING METHOD THEREOF

(71) Applicant: Shenzhen China Star Optoelectronics Technology Co., Ltd., Shenzhen City (CN)

(72) Inventor: Xiangyang Xu, Shenzhen City (CN)

(21) Appl. No.: 15/114,853

(22) PCT Filed: Jun. 17, 2016
(86) PCT No.: PCT/CN2016/086128

§ 371 Date: Jul. 28, 2016

(30) Foreign Application Priority Data
Jan. 13, 2016 (CN) 201610022486.8

(51) Int. Cl. G09G 3/36; G02F 1/1362; G02F 1/1368

(52) U.S. Cl. CPC G09G 3/3614; G09G 3/3677; G09G 3/3688; G02F 1/136286; G02F 1/1368; G09G 2330/021; H01L 27/124; G09G 2300/0478; G09G 2300/0823; G09G 2300/0426; G02F 2201/123; G02F 2201/52; G09G 2300/0443

(57) ABSTRACT

The present invention provides a liquid crystal display panel and a driving method thereof, in which the (4j)th and the (4j−3)th gate scan lines are arranged as first polarity gate scan lines and the (4j−1)th and the (4j−2)th gate scan lines are second polarity gate scan lines so that in driving the liquid crystal display panel, in a first half of frame for a frame period, a reversion signal (POL) controls the data lines to supply data signals of a first polarity, and the first polarity gate scan lines conduct first polarity scanning, in sequence from top to bottom, and in a second half of the frame, the reversion signal (POL) controls the data lines to supply data signals of a second polarity that is an opposite polarity, and the second polarity gate scan lines conduct second polarity scanning, in sequence from top to bottom, the reversion signal (POL) having a frequency equal to a frame frequency of the liquid crystal display panel, whereby the reversion frequency of the positive and negative polarity of the data signals can be greatly reduced, delays of the data signal can be effectively reduced, a charging effect to each of the sub-pixels can be ensured, a bright strip of a liquid crystal display panel having a dual gate structure can be eliminated, and driving power consumption can be lowered down.

### BACKGROUND OF THE INVENTION

### 1. Field of the Invention

The present invention relates to the field of display technology, and in particular to a liquid crystal display panel and a driving method thereof.

### 2. The Related Arts

Liquid crystal displays (LCDs) have a variety of advantages, such as thin device body, low power consumption, and being free of radiation, and thus have wide applications, such as liquid crystal televisions, mobile phones, personal digital assistants (PDAs), digital cameras, computer monitors, and notebook computer screens, so as to take a leading position in the field of flat panel displays.

Most of the LCDs that are currently available in the market are backlighting LCDs, which comprise a liquid crystal display panel and a backlight module. The working principle of the liquid crystal display panel is that liquid crystal molecules are filled between a thin-film transistor (TFT) array substrate and a color filter (CF) substrate and a drive voltage is applied to the two substrates to control a rotation direction of the liquid crystal molecules in order to refract out light emitting from the backlight module to generate an image.

The liquid crystal display panel comprises a plurality of sub-pixels arranged in an array. Each of the sub-pixels is electrically connected to a thin-film transistor (TFT). The TFT has a gate that is connected to a gate scan line arranged in a horizontal direction, a drain connected to a data line arranged in a vertical direction, and a source connected to a pixel electrode. Application of a sufficient voltage to the gate scan line would turn on all TFTs connected to the gate scan line to allow a signal voltage on the data line to be written into the pixel to control light transmission of liquid crystal thereby realizing an effect of displaying.

Referring to FIG. 1, a known dual gate liquid crystal display panel has a structure comprising multiple vertical data lines that are parallel to each other and are arranged sequentially one by one, multiple horizontal gate scan lines that are parallel to each other and are arranged sequentially one by one, and multiple sub-pixels arranged in an array. Corresponding to every two adjacent columns of sub-pixels, a data line is arranged between the two adjacent columns of sub-pixels and the two adjacent columns of sub-pixels are both electrically connected to the data line. For example, the sub-pixels of the first column and the second column are all electrically connected to the first data line D1; the sub-pixels of the third column and the fourth column are all electrically connected to the second data line D2; the sub-pixels of the fifth column and the sixth column are all electrically connected to the third data line D3, and so on. Corresponding to each row of sub-pixel, a gate scan line is arranged on each of upper and lower sides of the row of sub-pixel. For example, a first gate scan line G1 is arranged on the upper side of a first row of sub-pixels, a second gate scan line G2 is arranged on the lower side of the first row of sub-pixels, a third gate scan line G3 is arranged on the upper side of a second row of sub-pixels, a fourth gate scan line G4 is arranged on the lower side of the first row of sub-pixels, a fifth gate scan line G5 is arranged on the upper side of a third row of sub-pixels, a sixth gate scan line G6 is arranged on the lower side of the third row of sub-pixels, and so on. Assuming i is a positive integer, the sub-pixels of the (2i−1)th column are electrically connected to the gate scan lines that are located above the rows in which the sub-pixels are located, while the sub-pixel of the (2i)th column are electrically connected to the gate scan lines that are located below the rows in which the sub-pixels are located. Each row of sub-pixels comprises red sub-pixels R, green sub-pixels G, and blue sub-pixels B that are sequentially arranged in a repeated and cyclic manner. The sub-pixels that are located in the same column are of the same color. The above-described dual gate arrangement allows the number of the data lines to be reduced to one half so as to effectively lower down the production cost of a liquid crystal display panel.

Referring to FIG. 2, in combination with FIG. 1, a driving process of the known dual gate structure of the liquid crystal display panel is as follows. The gate scan lines supply, in sequence from the first one to the last one, gate scan signals and the data lines conduct charging operations on the sub-pixels. Taking the first data line D1 as an example, firstly, the first gate scan line G1 supplies a scan pulse signal and the first data line D1 charges a positive polarity data signal to the red sub-pixel R of the first row and the first column; and then the second gate scan line G2 supplies a scan pulse signal and the first data line D1 charges a negative polarity data signal to the green sub-pixel G of the first row and the second column; and then, the third gate scan line G3 supplies a scan pulse signal and the first data line D1 charges a negative polarity data signal to the red sub-pixel R of the second row and the first column; and then, the fourth gate scan line G4 supplies a scan pulse signal and the first data line D1 charges a positive polarity data signal to the green sub-pixel G of the second row and second column, and so on. During switching between positive and negative polarities (such as switching from a positive polarity to a negative polarity or from a negative polarity to a positive polarity) of the data signal supplied from a source driving circuit to the first data line, signal delay may occur on the data signal loaded in the first data line D1 so that the corresponding sub-pixel may be charged insufficiently, making the brightness of light emitting from the corresponding sub-pixel exceed ideal brightness. For the first data line D1, the time of the switching between positive and negative polarities of the data signal is always at the moment when the sub-pixels of the second column are charged so that the brightness of the second column of sub-pixels is relatively strong and a bright strip may be formed at the location of the second column of sub-pixels. Based on this, the liquid crystal display panel would exhibit a bright strip at a location corresponding to each of the data lines. The presence of the bright strips would affect the displaying quality of the display panel, causing unpleasant experience of a user. Further, as shown in FIG. 2, a reversion signal POL that controls the switching or reversion between the positive and negative polarities of the data signal has a frequency that is generally ½ of a clock signal CLK and the positive and negative polarities are switched or reversed a number of time in a display period of a frame of image so that the driving power of the liquid crystal display panel is relatively high.

### SUMMARY OF THE INVENTION

An object of the present invention is to provide a liquid crystal display panel, which reduces delay of a data signal to ensure a charging effect for each sub-pixel and eliminates a bright strip occurring in a displaying process of a liquid crystal display panel having a dual gate structure and lowers down signal reversion frequency and driving power consumption of the liquid crystal display panel.

Another object of the present invention is to provide a driving method of a liquid crystal display panel, which reduces delay of a data signal to ensure a charging effect for each sub-pixel and eliminates a bright strip occurring in a displaying process of a liquid crystal display panel having a dual gate structure and lowers down signal reversion frequency and driving power consumption of the liquid crystal display panel.

To achieve the above objects, the present invention provides a liquid crystal display panel, which comprises: a plurality of data lines that are vertical, parallel to each other, and arranged sequentially one by one, a plurality of gate scan lines that are horizontal, parallel to each other, and arranged sequentially one by one, and a plurality of sub-pixels arranged in an array;

wherein corresponding to every two adjacent ones of columns of the sub-pixels, one of the data lines is arranged between the two adjacent columns of the sub-pixels such that the sub-pixels of the two columns are all electrically connected to the data line;

corresponding to each of rows of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located;

the first to last gate scan lines are arranged, in sequence, from top to bottom, wherein assuming j is a positive integer, the (4j)th and (4j−3)th gate scan lines are first polarity gate scan lines and the (4j−1)th and (4j−2)th gate scan lines are second polarity gate scan lines;

in driving the liquid crystal display panel, in a first half of a frame for a frame period, the data lines supply data signals of a first polarity and the first polarity gate scan lines conduct first polarity scanning in sequence from top to bottom; and in a second half of the frame, the data lines supply data signals of a second polarity and the second polarity gate scan lines conduct second polarity scanning in sequence from top to bottom; and

the first polarity and the second polarity are opposite polarities.

The sub-pixels comprise red sub-pixels, green sub-pixels, and blue sub-pixels that are arranged, repeatedly and cyclically, in a horizontal direction from left to right and a display pixel is formed of one of the red sub-pixels, one of the green sub-pixels, and one of the blue sub-pixels.

Optionally, first polarity is a positive polarity and the second polarity is a negative polarity. The reversion signal controls reversion of polarity of the data signal. The reversion signal has a frequency corresponding to a frame frequency of the liquid crystal display panel.

Optionally, the first polarity is a negative polarity and the second polarity is a positive polarity. The reversion signal controls reversion of polarity of the data signal. The reversion signal has a frequency corresponding to a frame frequency of the liquid crystal display panel.

Each of the sub-pixels comprises a thin-film transistor and a pixel electrode electrically connected to the thin-film transistor; and the thin-film transistor has a gate electrode electrically connected to the gate scan line that corresponds to the sub-pixel, a source electrode electrically connected to the data line that corresponds to the sub-pixel, and a drain electrode electrically connected to the pixel electrode.

The present invention also provides a driving method of a liquid crystal display panel, which comprises the following steps:

(1) providing a liquid crystal display panel,

wherein the liquid crystal display panel comprises: a plurality of data lines that are vertical, parallel to each other, and arranged sequentially one by one, a plurality of gate scan lines that are horizontal, parallel to each other, and arranged sequentially one by one, and a plurality of sub-pixels arranged in an array;

corresponding to every two adjacent ones of columns of the sub-pixels, one of the data lines is arranged between the two adjacent columns of the sub-pixels such that the sub-pixels of the two columns are all electrically connected to the data line; and

corresponding to each of rows of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located;

(2) conducting first frame half scanning, wherein a reversion signal controls the data lines to supply data signals of a first polarity, where assuming j is a positive integer, (4j)th and (4j−3)th gate scan lines conduct scanning in sequence from top to bottom to have the sub-pixels that are electrically connected to the (4j)th and the (4j−3)th gate scan lines exhibiting the first polarity; and

(3) conducting second frame half scanning, wherein the reversion signal controls the data lines to supply data signals of a second polarity that are of a polarity opposite to the data signals of the first polarity, where (4j−1)th and (4j−2)th gate scan lines conduct scanning in sequence from top to bottom to have the sub-pixels that are electrically connected to the (4j−1)th and the (4j−2)th gate scan lines exhibiting the second polarity.

The reversion signal has a frequency corresponding to a frame frequency of the liquid crystal display panel.

The sub-pixels comprise red sub-pixels, green sub-pixels, and blue sub-pixels that are arranged, repeatedly and cyclically, in a horizontal direction from left to right and a display pixel is formed of one of the red sub-pixels, one of the green sub-pixels, and one of the blue sub-pixels.

In step (2), a first scan triggering signal is supplied to the liquid crystal display panel to start up the first frame half scanning; and in step (3), a second scan triggering signal is supplied to the liquid crystal display panel to start up the second frame half scanning.

Each of the sub-pixels comprises a thin-film transistor and a pixel electrode electrically connected to the thin-film transistor; and the thin-film transistor has a gate electrode electrically connected to the gate scan line that corresponds to the sub-pixel, a source electrode electrically connected to the data line that corresponds to the sub-pixel, and a drain electrode electrically connected to the pixel electrode.

The present invention further provides a liquid crystal display panel, which comprises: a plurality of data lines that are vertical, parallel to each other, and arranged sequentially one by one, a plurality of gate scan lines that are horizontal, parallel to each other, and arranged sequentially one by one, and a plurality of sub-pixels arranged in an array;

wherein corresponding to every two adjacent ones of columns of the sub-pixels, one of the data lines is arranged between the two adjacent columns of the sub-pixels such that the sub-pixels of the two columns are all electrically connected to the data line;

corresponding to each of rows of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located;

the first to last gate scan lines are arranged, in sequence, from top to bottom, wherein assuming j is a positive integer, the (4j)th and (4j−3)th gate scan lines are first polarity gate scan lines and the (4j−1)th and (4j−2)th gate scan lines are second polarity gate scan lines;

in driving the liquid crystal display panel, in a first half of a frame for a frame period, the data lines supply data signals of a first polarity and the first polarity gate scan lines conduct first polarity scanning in sequence from top to bottom; and in a second half of the frame, the data lines supply data signals of a second polarity and the second polarity gate scan lines conduct second polarity scanning in sequence from top to bottom; and

the first polarity and the second polarity are opposite polarities;

wherein the sub-pixels comprise red sub-pixels, green sub-pixels, and blue sub-pixels that are arranged, repeatedly and cyclically, in a horizontal direction from left to right and a display pixel is formed of one of the red sub-pixels, one of the green sub-pixels, and one of the blue sub-pixels; and

wherein each of the sub-pixels comprises a thin-film transistor and a pixel electrode electrically connected to the thin-film transistor; and the thin-film transistor has a gate electrode electrically connected to the gate scan line that corresponds to the sub-pixel, a source electrode electrically connected to the data line that corresponds to the sub-pixel, and a drain electrode electrically connected to the pixel electrode.

The efficacy of the present invention is that the present invention provides a liquid crystal display panel and a driving method thereof, in which the (4j)th and the (4j−3)th gate scan lines are arranged as first polarity gate scan lines and the (4j−1)th and the (4j−2)th gate scan lines are second polarity gate scan lines so that in driving the liquid crystal display panel, in a first half of frame for a frame period, a reversion signal controls the data lines to supply data signals of a first polarity, and the first polarity gate scan lines conduct first polarity scanning, in sequence from top to bottom, and in a second half of the frame, the reversion signal controls the data lines to supply data signals of a second polarity that is opposite in polarity to the data signal of the first polarity, and the second polarity gate scan lines conduct second polarity scanning, in sequence from top to bottom, the reversion signal having a frequency equal to a frame frequency of the liquid crystal display panel, whereby, compared to the prior art, the reversion frequency of the positive and negative polarity of the data signals can be greatly reduced, delays of the data signal can be effectively reduced, a charging effect to each of the sub-pixels can be ensured, a bright strip occurring in a displaying process of a liquid crystal display panel having a dual gate structure can be eliminated, and driving power consumption of the liquid crystal display panel can be lowered down.

### BRIEF DESCRIPTION OF THE DRAWINGS

The features and technical contents of the present invention will be better understood by referring to the following detailed description and drawings the present invention. However, the drawings are provided for the purpose of reference and illustration and are not intended to limit the scope of the present invention. In the drawing:

FIG. 1 is a schematic view illustrating a conventional liquid crystal display panel having a dual gate line structure;

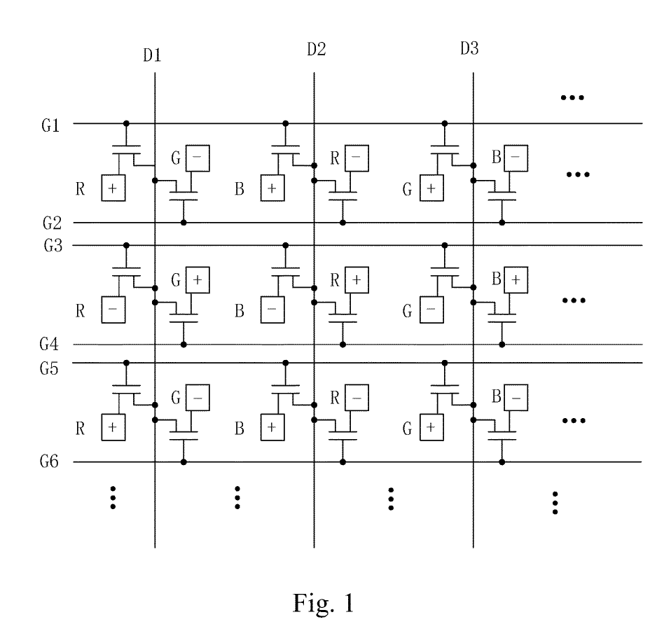

FIG. 2 is a driving timing diagram of the liquid crystal display panel shown in FIG. 1;

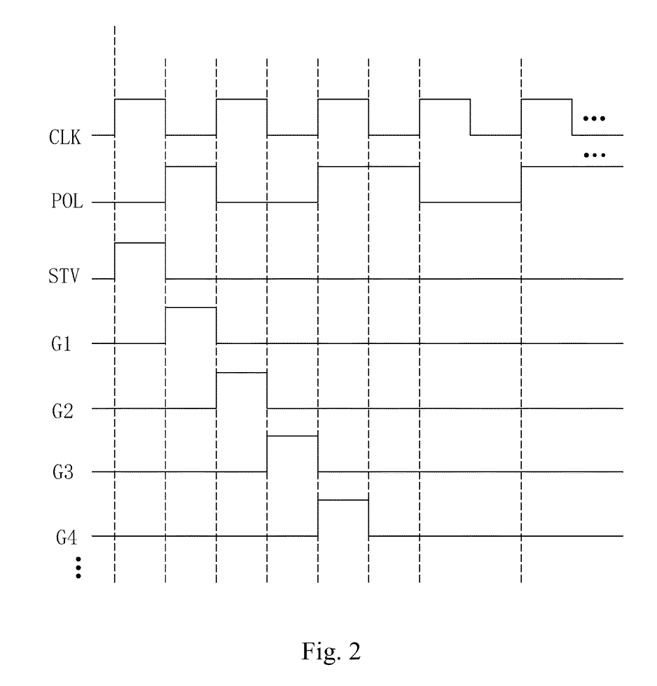

FIG. 3 is a schematic view illustrating a liquid crystal display panel according to the present invention;

FIG. 4 is a driving timing diagram of the liquid crystal display panel according to the present invention;

FIG. 5 is a schematic view illustrating pixel refreshing of the liquid crystal display panel according to the present invention in a first half of a frame;

FIG. 6 is a schematic view illustrating pixel refreshing of the liquid crystal display panel according to the present invention in a second half of a frame; and

FIG. 7 is a flow chart illustrating a driving method of a liquid crystal display panel according to the present invention.

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

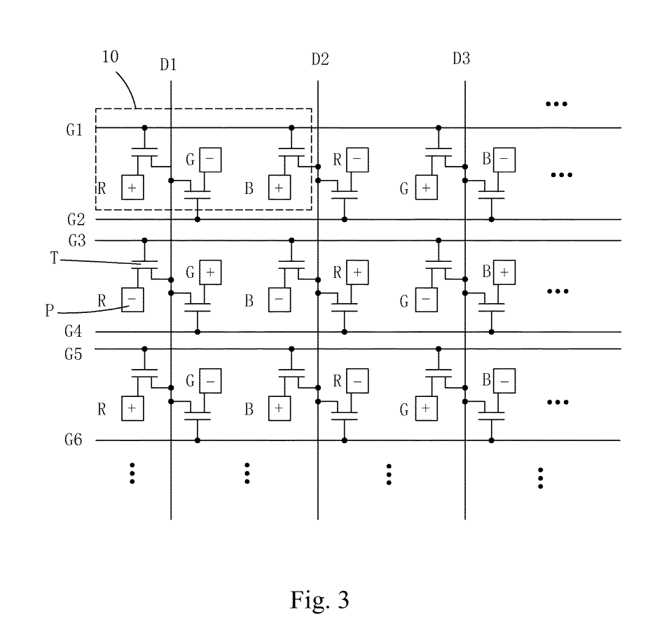

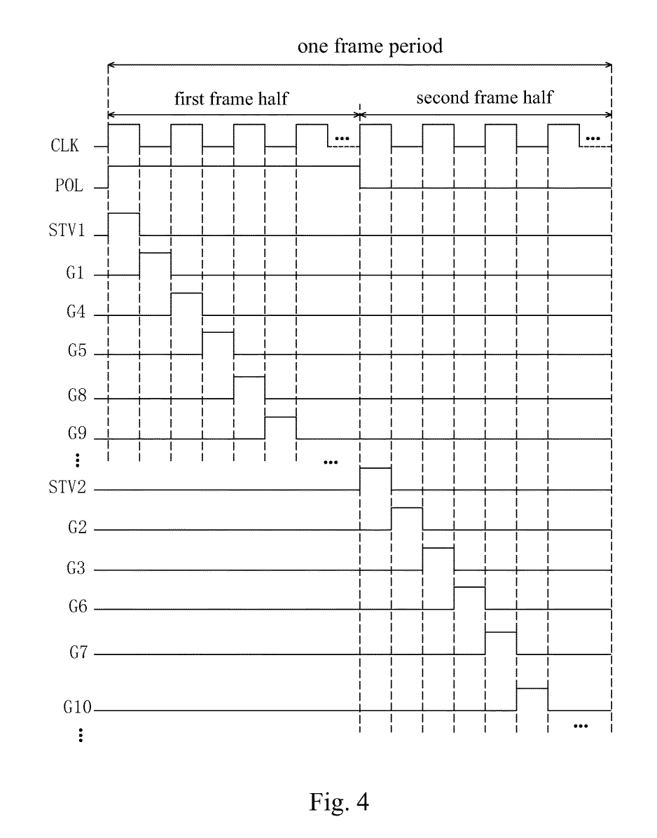

Referring collectively to FIGS. 3 and 4, firstly, the present invention provides a liquid crystal display panel, which comprises: a plurality of data lines (such as D1, D2, D3 and so on) that are vertical, parallel to each other, and arranged sequentially one by one, a plurality of gate scan lines (such as G1, G2, G3, G4, G5, G6, and son on) that are horizontal, parallel to each other, and arranged sequentially one by one, and a plurality of sub-pixels arranged in an array.

Specifically, as shown in FIG. 3, the sub-pixels comprise red sub-pixels R, green sub-pixels G, and blue sub-pixels B that are arranged, repeatedly and cyclically, in a horizontal direction from left to right and a display pixel 10 is formed of one red sub-pixel R, one green sub-pixel G, and one blue sub-pixel B. The sub-pixels that are arranged in the same column are of the same color.

Each of the sub-pixels comprises a thin-film transistor T and a pixel electrode P electrically connected to the thin-film transistor T. The thin-film transistor T has a gate electrode electrically connected to the gate scan line that corresponds to the sub-pixel, a source electrode electrically connected to the data line that corresponds to the sub-pixel, and a drain electrode electrically connected to the pixel electrode P.

Further, corresponding to every two adjacent columns of the sub-pixels, one of the data lines is arranged between the two adjacent columns of the sub-pixels such that the sub-pixels of the two columns are all electrically connected to the data line. For example, the red sub-pixels R of the first column and the green sub-pixels G of the second column are all electrically connected to the first data line D1; the blue sub-pixels B of the third column and the red sub-pixels R of the fourth column are all electrically connected to the second data line D2; the green sub-pixels G of the fifth column and the blue sub-pixels B of the sixth column are all electrically connected to the third data line D3, and so on. Corresponding to each row of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located. For example, a first gate scan line G1 is disposed above the first row of the sub-pixels and a second gate scan line G2 is disposed below the first row of the sub-pixels, where the sub-pixels of the first row in the odd columns are electrically connected to the first gate scan line G1 and the sub-pixels of the first row in the odd columns are electrically connected to the second gate scan line G2; a third gate scan line G3 is disposed above the second row of the sub-pixels and a fourth gate scan line G4 is disposed below the second row of the sub-pixels, where the sub-pixels of the second row in the odd columns are electrically connected to the third gate scan line G3 and the sub-pixels of the second row in the odd columns are electrically connected to the fourth gate scan line G4; a fifth gate scan line G5 is disposed above the third row of the sub-pixels and a sixth gate scan line G6 is disposed below the third row of the sub-pixels, where the sub-pixels of the third row in the odd columns are electrically connected to the fifth gate scan line G5 and the sub-pixels of the third row in the odd columns are electrically connected to the sixth gate scan line G6, and so on.

It is particularly noted here that the first to last gate scan lines are arranged, in sequence, from top to bottom. Assuming j is a positive integer, the (4j)th and (4j−3)th gate scan lines, such as G1, G4, G5, G8, G9, are first polarity gate scan lines, and the (4j−1)th and (4j−2)th gate scan lines, such as G2, G3, G6, G7, G10, are second polarity gate scan lines.

Referring to FIG. 4, in a first half of frame for a frame period, a reversion signal POL controls the data lines to supply data signals of a first polarity, and the first polarity gate scan lines conduct first polarity scanning, in sequence from top to bottom, so as to have the sub-pixels that are electrically connected to the first polarity gate scan lines, namely the (4j)th and (4j−3)th gate scan lines, exhibiting the first polarity; and in a second half of the frame, the reversion signal POL controls the data lines to supply data signals of a second polarity, and the second polarity gate scan lines conduct second polarity scanning, in sequence from top to bottom, so as to have the sub-pixels that are electrically connected to the second polarity gate scan lines, namely the (4j−1)th and (4j−2)th gate scan lines, exhibiting the first polarity. The first polarity and the second polarity are opposite to each other. Switching of the polarities of the data signals is controlled by the reversion signal POL. For each frame period, the reversion signal POL reverses the polarity one time and controls the polarity of the data signal to reverse one time. In other words, the reversion signal POL has a period that is equal to the frame period and the reversion signal POL has a frequency that is equal to a frame frequency of the liquid crystal display panel. Each frame period comprises a plurality of periods of a clock signal CLK so that, on the same basis of point reversion, compared to the prior art, the liquid crystal display panel of the present invention greatly reduces the frequency of switching or reversing the positive/negative polarities of the data signals to thereby effectively reduce delays of the data signals, ensures a charging effect of each of the sub-pixels, eliminate a bright strip occurring in a displaying process of a liquid crystal display panel having a dual gate structure, and lower down driving power consumption of the liquid crystal display panel.

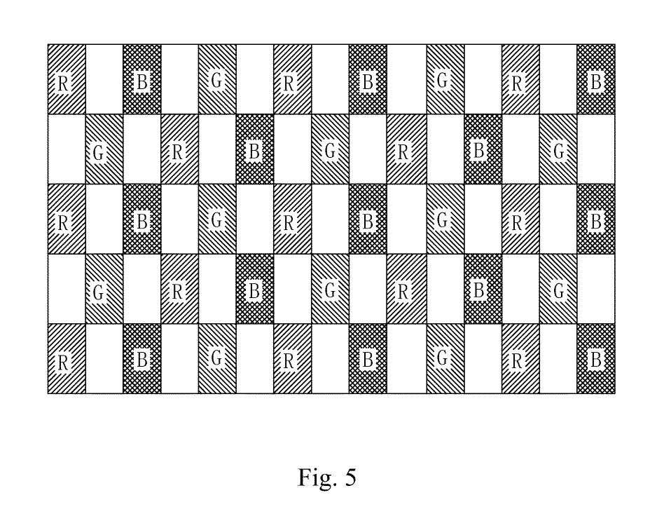

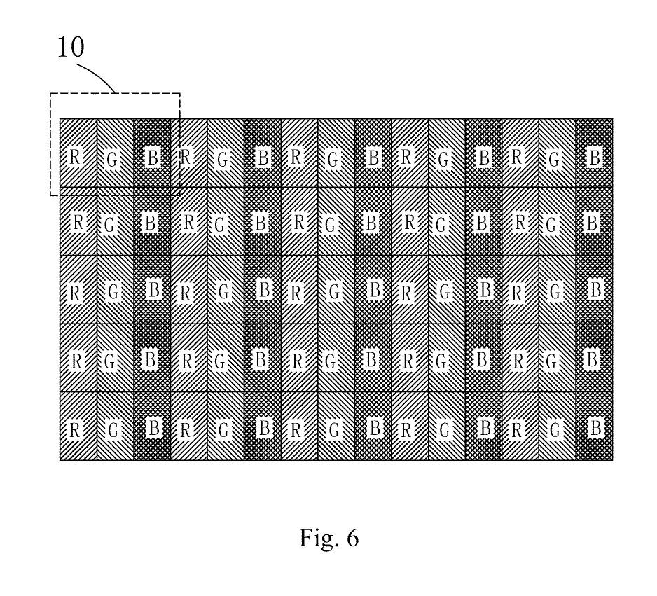

Optionally, the first polarity is a positive polarity and, as shown in FIG. 5, in the first half of a frame for a frame period, the sub-pixels of odd rows in odd columns and the sub-pixels of even rows in even columns are all in positive polarity for displaying; and the second polarity is a negative polarity, as shown in FIG. 6, in the second half of the frame for the frame period, the sub-pixels of odd rows in even columns and the sub-pixels of even rows in odd columns are all in negative polarity for displaying.

It is apparent that the first polarity can be a negative polarity and the second polarity is a positive polarity.

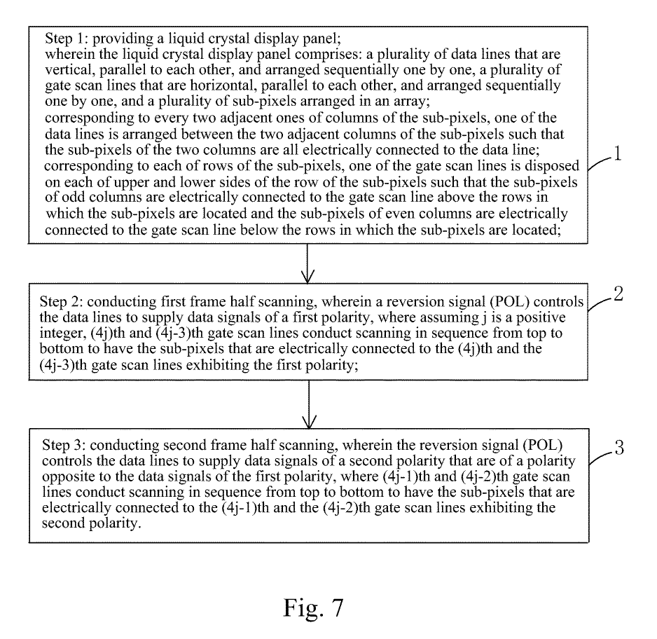

Referring to FIG. 7, in combination with FIGS. 3 and 4, the present invention also provides a driving method of a liquid crystal display panel, which comprises the followings steps:

Step 1: providing a liquid crystal display panel.

The liquid crystal display panel comprises: a plurality of data lines (such as D1, D2, D3 and so on) that are vertical, parallel to each other, and arranged sequentially one by one, a plurality of gate scan lines (such as G1, G2, G3, G4, G5, G6, and so on) that are horizontal, parallel to each other, and arranged sequentially one by one, and a plurality of sub-pixels arranged in an array.

Specifically, as shown in FIG. 3, the sub-pixels comprise red sub-pixels R, green sub-pixels G, and blue sub-pixels B that are arranged, repeatedly and cyclically, in a horizontal direction from left to right and a display pixel 10 is formed of one red sub-pixel R, one green sub-pixel G, and one blue sub-pixel B. The sub-pixels that are arranged in the same column are of the same color.

Each of the sub-pixels comprises a thin-film transistor T and a pixel electrode P electrically connected to the thin-film transistor T. The thin-film transistor T has a gate electrode electrically connected to the gate scan line that corresponds to the sub-pixel, a source electrode electrically connected to the data line that corresponds to the sub-pixel, and a drain electrode electrically connected to the pixel electrode P.

Further, corresponding to every two adjacent columns of the sub-pixels, one of the data lines is arranged between the two adjacent columns of the sub-pixels such that the sub-pixels of the two columns are all electrically connected to the data line. For example, the red sub-pixels R of the first column and the green sub-pixels G of the second column are all electrically connected to the first data line D1; the blue sub-pixels B of the third column and the red sub-pixels R of the fourth column are all electrically connected to the second data line D2; the green sub-pixels G of the fifth column and the blue sub-pixels B of the sixth column are all electrically connected to the third data line D3, and so on. Corresponding to each row of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located. For example, a first gate scan line G1 is disposed above the first row of the sub-pixels and a second gate scan line G2 is disposed below the first row of the sub-pixels, where the sub-pixels of the first row in the odd columns are electrically connected to the first gate scan line G1 and the sub-pixels of the first row in the odd columns are electrically connected to the second gate scan line G2; a third gate scan line G3 is disposed above the second row of the sub-pixels and a fourth gate scan line G4 is disposed below the second row of the sub-pixels, where the sub-pixels of the second row in the odd columns are electrically connected to the third gate scan line G3 and the sub-pixels of the second row in the odd columns are electrically connected to the fourth gate scan line G4; a fifth gate scan line G5 is disposed above the third row of the sub-pixels and a sixth gate scan line G6 is disposed below the third row of the sub-pixels, where the sub-pixels of the third row in the odd columns are electrically connected to the fifth gate scan line G5 and the sub-pixels of the third row in the odd columns are electrically connected to the sixth gate scan line G6, and so on.

Step 2: conducting first frame half scanning, wherein, referring to FIGS. 3 and 4, a reversion signal POL controls the data lines to supply data signals of a first polarity, where assuming j is a positive integer, (4j)th and (4j−3)th gate scan lines conduct scanning in sequence from top to bottom to have the sub-pixels that are electrically connected to the (4j)th and the (4j−3)th gate scan lines exhibiting the first polarity.

Step 3: conducting second frame half scanning, wherein, referring to FIGS. 3 and 4, the reversion signal POL controls the data lines to supply data signals of a second polarity that are of a polarity opposite to the data signals of the first polarity, where (4j−1)th and (4j−2)th gate scan lines conduct scanning in sequence from top to bottom to have the sub-pixels that are electrically connected to the (4j−1)th and the (4j−2)th gate scan lines exhibiting the second polarity.

Specifically, the reversion signal POL has a frequency that is equal to a frame frequency of the liquid crystal display panel. Step 2 starts up the first frame half scanning by supplying a first scan triggering signal STV1 to the liquid crystal display panel; and Step 3 starts up the second frame half scanning by supplying a second scan triggering signal STV2 to the liquid crystal display panel.

Optionally, the first polarity is a positive polarity and the second polarity is a negative polarity, or alternatively, the first polarity is a negative polarity and the second polarity is a positive polarity.

The present invention provides a driving method of a liquid crystal display panel, in which a reversion signal POL controls polarity reversion of the data signal. For each frame period, the reversion signal POL reverses the polarity one time and controls the polarity of the data signal to reverse one time. In other words, the reversion signal POL has a period that is equal to the frame period and the reversion signal POL has a frequency that is equal to a frame frequency of the liquid crystal display panel. Each frame period comprises a plurality of periods of a clock signal CLK so that, on the same basis of point reversion, compared to the prior art, the liquid crystal display panel of the present invention greatly reduces the frequency of switching or reversing the positive/negative polarities of the data signals to thereby effectively reduce delays of the data signals, ensures a charging effect of each of the sub-pixels, eliminate a bright strip occurring in a displaying process of a liquid crystal display panel having a dual gate structure, and lower down driving power consumption of the liquid crystal display panel.

In summary, the present invention provides a liquid crystal display panel and a driving method thereof, in which the (4j)th and the (4j−3)th gate scan lines are arranged as first polarity gate scan lines and the (4j−1)th and the (4j−2)th gate scan lines are second polarity gate scan lines so that in driving the liquid crystal display panel, in a first half of frame for a frame period, a reversion signal controls the data lines to supply data signals of a first polarity, and the first polarity gate scan lines conduct first polarity scanning, in sequence from top to bottom, and in a second half of the frame, the reversion signal controls the data lines to supply data signals of a second polarity that is opposite in polarity to the data signal of the first polarity, and the second polarity gate scan lines conduct second polarity scanning, in sequence from top to bottom, the reversion signal having a frequency equal to a frame frequency of the liquid crystal display panel, whereby, compared to the prior art, the reversion frequency of the positive and negative polarity of the data signals can be greatly reduced, delays of the data signal can be effectively reduced, a charging effect to each of the sub-pixels can be ensured, a bright strip occurring in a displaying process of a liquid crystal display panel having a dual gate structure can be eliminated, and driving power consumption of the liquid crystal display panel can be lowered down.

Based on the description given above, those having ordinary skills of the art may easily contemplate various changes and modifications of the technical solution and technical ideas of the present invention and all these changes and modifications are considered within the protection scope of right for the present invention as defined in the appended claims.

What is claimed is:

1. A liquid crystal display panel, comprising: a plurality of data lines that are vertical, parallel to each other, and arranged sequentially one by one, a plurality of gate scan lines that are horizontal, parallel to each other, and arranged sequentially one by one, and a plurality of sub-pixels arranged in an array;
wherein corresponding to every two adjacent ones of columns of the sub-pixels, one of the data lines is arranged between the two adjacent columns of the sub-pixels such that the sub-pixels of the two columns are all electrically connected to the data line;
corresponding to each of rows of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located;
the first to last gate scan lines are arranged, in sequence, from top to bottom, wherein assuming j is a positive integer, the (4j)th and (4j−3)th gate scan lines are first polarity gate scan lines and the (4j−1)th and (4j−2)th gate scan lines are second polarity gate scan lines;
in driving the liquid crystal display panel, in a first half of a frame for a frame period, the data lines supply data signals of a first polarity and the first polarity gate scan lines conduct first polarity scanning in sequence from top to bottom; and in a second half of the frame, the data lines supply data signals of a second polarity and the second polarity gate scan lines conduct second polarity scanning in sequence from top to bottom; and
the first polarity and the second polarity are opposite polarities.

2. The liquid crystal display panel as claimed in claim 1, wherein the sub-pixels comprise red sub-pixels, green sub-pixels, and blue sub-pixels that are arranged, repeatedly and cyclically, in a horizontal direction from left to right and a display pixel is formed of one of the red sub-pixels, one of the green sub-pixels, and one of the blue sub-pixels.

3. The liquid crystal display panel as claimed in claim 1, wherein the first polarity is a positive polarity and the second polarity is a negative polarity, the reversion signal controlling reversion of polarity of the data signal, the reversion signal having a frequency corresponding to a frame frequency of the liquid crystal display panel.

4. The liquid crystal display panel as claimed in claim 1, wherein the first polarity is a negative polarity and the second polarity is a positive polarity, the reversion signal controlling reversion of polarity of the data signal, the reversion signal having a frequency corresponding to a frame frequency of the liquid crystal display panel.

5. The liquid crystal display panel as claimed in claim 1, wherein each of the sub-pixels comprises a thin-film transistor and a pixel electrode electrically connected to the thin-film transistor; and the thin-film transistor has a gate electrode electrically connected to the gate scan line that corresponds to the sub-pixel, a source electrode electrically connected to the data line that corresponds to the sub-pixel, and a drain electrode electrically connected to the pixel electrode.

6. A driving method of a liquid crystal display panel, comprising the following steps:
(1) providing a liquid crystal display panel,
wherein the liquid crystal display panel comprises: a plurality of data lines that are vertical, parallel to each other, and arranged sequentially one by one, a plurality of gate scan lines that are horizontal, parallel to each other, and arranged sequentially one by one, and a plurality of sub-pixels arranged in an array;
corresponding to every two adjacent ones of columns of the sub-pixels, one of the data lines is arranged between the two adjacent columns of the sub-pixels such that the sub-pixels of the two columns are all electrically connected to the data line; and
corresponding to each of rows of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located;
(2) conducting first frame half scanning, wherein a reversion signal controls the data lines to supply data signals of a first polarity, where assuming j is a positive integer, (4j)th and (4j−3)th gate scan lines conduct scanning in sequence from top to bottom to have the sub-pixels that are electrically connected to the (4j)th and the (4j−3)th gate scan lines exhibiting the first polarity; and
(3) conducting second frame half scanning, wherein the reversion signal controls the data lines to supply data signals of a second polarity that are of a polarity opposite to the data signals of the first polarity, where (4j−1)th and (4j−2)th gate scan lines conduct scanning in sequence from top to bottom to have the sub-pixels that are electrically connected to the (4j−1)th and the (4j−2)th gate scan lines exhibiting the second polarity.

7. The driving method of the liquid crystal display panel as claimed in claim 6, wherein the reversion signal has a frequency corresponding to a frame frequency of the liquid crystal display panel.

8. The driving method of the liquid crystal display panel as claimed in claim 6, wherein the sub-pixels comprise red sub-pixels, green sub-pixels, and blue sub-pixels that are arranged, repeatedly and cyclically, in a horizontal direction from left to right and a display pixel is formed of one of the red sub-pixels, one of the green sub-pixels, and one of the blue sub-pixels.

9. The driving method of the liquid crystal display panel as claimed in claim 6, wherein in step (2), a first scan triggering signal is supplied to the liquid crystal display panel to start up the first frame half scanning; and in step (3), a second scan triggering signal is supplied to the liquid crystal display panel to start up the second frame half scanning.

10. The driving method of the liquid crystal display panel as claimed in claim 6, wherein each of the sub-pixels comprises a thin-film transistor and a pixel electrode electrically connected to the thin-film transistor; and the thin-film transistor has a gate electrode electrically connected to the gate scan line that corresponds to the sub-pixel, a source electrode electrically connected to the data line that corresponds to the sub-pixel, and a drain electrode electrically connected to the pixel electrode.

11. A liquid crystal display panel, comprising: a plurality of data lines that are vertical, parallel to each other, and arranged sequentially one by one, a plurality of gate scan lines that are horizontal, parallel to each other, and arranged sequentially one by one, and a plurality of sub-pixels arranged in an array;
wherein corresponding to every two adjacent ones of columns of the sub-pixels, one of the data lines is arranged between the two adjacent columns of the sub-pixels such that the sub-pixels of the two columns are all electrically connected to the data line;
corresponding to each of rows of the sub-pixels, one of the gate scan lines is disposed on each of upper and lower sides of the row of the sub-pixels such that the sub-pixels of odd columns are electrically connected to the gate scan line above the rows in which the sub-pixels are located and the sub-pixels of even columns are electrically connected to the gate scan line below the rows in which the sub-pixels are located;
the first to last gate scan lines are arranged, in sequence, from top to bottom, wherein assuming j is a positive integer, the (4j)th and (4j−3)th gate scan lines are first polarity gate scan lines and the (4j−1)th and (4j−2)th gate scan lines are second polarity gate scan lines;
in driving the liquid crystal display panel, in a first half of a frame for a frame period, the data lines supply data signals of a first polarity and the first polarity gate scan lines conduct first polarity scanning in sequence from top to bottom; and in a second half of the frame, the data lines supply data signals of a second polarity and the second polarity gate scan lines conduct second polarity scanning in sequence from top to bottom; and
the first polarity and the second polarity are opposite polarities;
wherein the sub-pixels comprise red sub-pixels, green sub-pixels, and blue sub-pixels that are arranged, repeatedly and cyclically, in a horizontal direction from left to right and a display pixel is formed of one of the red sub-pixels, one of the green sub-pixels, and one of the blue sub-pixels; and
wherein each of the sub-pixels comprises a thin-film transistor and a pixel electrode electrically connected to the thin-film transistor; and the thin-film transistor has a gate electrode electrically connected to the gate scan line that corresponds to the sub-pixel, a source electrode electrically connected to the data line that corresponds to the sub-pixel, and a drain electrode electrically connected to the pixel electrode.

12. The liquid crystal display panel as claimed in claim 11, wherein the first polarity is a positive polarity and the second polarity is a negative polarity, the reversion signal controlling reversion of polarity of the data signal, the reversion signal having a frequency corresponding to a frame frequency of the liquid crystal display panel.

13. The liquid crystal display panel as claimed in claim 11, wherein the first polarity is a negative polarity and the second polarity is a positive polarity, the reversion signal controlling reversion of polarity of the data signal, the reversion signal having a frequency corresponding to a frame frequency of the liquid crystal display panel.
